(19) United States
(12) Patent Application Publication
(10) Pub. No.: US 2012/0304935 A1
(43) Pub. Date: Dec. 6, 2012

(54) BUBBLER ASSEMBLY AND METHOD FOR VAPOR FLOW CONTROL

(76) Inventors: Theodorus G.M. Oosterlaken, Almere (NL); Jan T.M. van Eijden, Almere (NL)

(21) Appl. No.: 13/118,953

(22) Filed: May 31, 2011

(51) Int. Cl. B01F 3/04; C23C 16/455; H01L 21/00; F15D 1/00

(52) U.S. Cl. 118/726; 261/121.1; 261/153; 261/137; 137/1

(57) ABSTRACT

Disclosed is a bubbler assembly. The bubbler assembly includes a vessel configured to contain a liquid source material and its vapor. It also includes a carrier gas supply line, a downstream end of which discharges in a lower portion of the vessel, and a gas outlet line, an upstream end of which is in fluid communication with an upper portion of the vessel. The gas outlet line includes a constriction. The bubbler assembly further includes a pressurizing gas supply line, a downstream end of which discharges in either the upper portion of the vessel or in the gas outlet line at a point upstream of the constriction.

### FIELD OF THE INVENTION

The present invention relates to a method and a system for controlling a flow of vaporized liquid material, which flow is generated by means of a bubbler and may subsequently be transported to a reactor.

### BACKGROUND

A bubbler is a device known in the art used to generate and control a flow of vaporized liquid source material to a reactor or processing chamber. A bubbler may typically include a generally sealed vessel containing the liquid source material, a carrier gas supply line that discharges into a lower portion of the vessel at a point below the surface level of the source material, and an outlet line that is in fluid communication with an upper portion of the vessel at a point above the surface level of the source material, and that runs from the vessel to the reactor. In operation a flow of inert carrier gas is driven through the carrier gas supply line. At the downstream end of the supply line, the flow breaks up and the carrier gas bubbles through the liquid phase of the source material so as to be saturated with its vapor. Upon surfacing, the mixture of carrier gas and source material vapor accumulates in the upper region of the vessel, from where it is discharged to the reactor via the outlet line.

Consistent optimal reactor performance demands that the source material vapor flow rate to the reactor can be controlled accurately. Since the flow rates of the source material vapor and the carrier gas through the gas lines of the bubbler are linked to each other, such control over the source material flow rate may be exercised by means of a mass flow controller (MFC) that is incorporated in the carrier gas supply line. The relationship between the carrier gas flow rate and the source material flow rate may generally be such that a greater carrier gas supply flow rate corresponds to a greater source material vapor flow rate, while a smaller carrier gas supply flow rate corresponds to a smaller precursor gas delivery flow rate. This control method may work satisfactorily for certain ranges of MFC flow rate settings and source material flow rates.

### SUMMARY OF THE INVENTION

However, when the equilibrium vapor pressure of the source material is of the same order or greater than a process pressure maintained in the reactor, which may for example be the case when the reactor is used for performing low pressure chemical vapor deposition (LPCVD), the delivery of source material vapor at small flow rates is problematic. This is because the equilibrium vapor pressure of the source material is essentially the smallest possible or minimum pressure in the vessel, and it corresponds to a minimum source material vapor flow rate that will be present even when the carrier gas flow rate is set to zero. Smaller flow rates than this minimum flow rate can thus not be obtained via control over the carrier gas flow rate.

US 2010/0178423 (Shimizu et al.) appears to address this problem as it discloses a method of controlling the source material vapor flow rate of source materials with a relatively high vapor pressure. US'423 proposes a bubbler setup featuring two serially connected Automatic Pressure Regulators (APR). A first APR is incorporated in a carrier gas supply line to a vessel containing liquid source material, and serves to control the (overall) pressure in the vessel. A second APR is incorporated in the gas outlet line, upstream of a constriction provided therein, and serves to control the pressure upstream of the constriction and hence, the flow through the constriction. The configuration of US'423 has a number of drawbacks. Firstly, the second APR is exposed to the source material, which practically means it must be heated to a temperature at least above the melting point of the source material to prevent condensation. Furthermore, APRs have certain characteristics that need to be taken into account. For example, for proper operation an APR requires a sufficiently large pressure difference between its upstream and downstream sides; an APR is not a shut-off valve, and if for some time an insufficient flow is provided the pressures at upstream and downstream ends will equalize. Finally, electronically controlled APR's are relatively expensive components which render the bubbler setup of US'423 rather costly.

It is an object of the present invention to provide for a bubbler and a method that mitigate or overcome one or more of these drawbacks of known bubblers in a cost-effective manner.

To this end, a first aspect of the invention is directed to a bubbler assembly. The bubbler assembly includes a vessel configured to contain a liquid source material and its vapor. It also includes a carrier gas supply line, a downstream end of which discharges in a lower portion of the vessel, and a gas outlet line, an upstream end of which is in fluid communication with an upper portion of the vessel. The gas outlet line includes a constriction. The bubbler assembly further includes a pressurizing gas supply line, a downstream end of which discharges in either the upper portion of the vessel or in the gas outlet line at a point upstream of the constriction.

A second aspect of the invention is directed to a method for controlling a flow of vaporized liquid material. The method includes providing a bubbler assembly according to the first aspect of the invention, wherein the vessel is partly filled with a liquid source material. The method also includes supplying a flow of carrier gas through the carrier gas supply line, which carrier gas supply line discharges below a surface level of the liquid source material in the vessel, such that the carrier gas bubbles through the liquid source material while being enriched in its vapor. The method further includes, while supplying the flow of carrier gas, supplying a flow of pressurizing gas through the pressurizing gas supply line, which pressurizing gas supply line discharges in either the upper portion of the vessel above the surface level of the liquid source material, or in the gas outlet line at a point upstream of the constriction. In addition, the method includes enabling a mixture comprising carrier gas, pressurizing gas and source material vapor to flow through the outlet line towards a downstream end thereof.

The bubbler assembly and the method according to the present invention utilize the fact that the concentration of the source material vapor in the gas mixture that is outputted via the outlet line of the bubbler assembly depends on the ratio between the equilibrium vapor pressure of the source material and the overall gas pressure in the vessel. The pressurizing gas flow rate (and other parameters, as is clarified infra) may be used to coarsely set and/or adjust this vessel pressure, so as to select a range of source material vapor flow rates that can be controlled by means of variations within the domain of selectable carrier gas flow rates.

In relation to the bubbler of US'423, it may be noted that the two (parallelly connected) MFCs of the bubbler assembly according to the present invention are only exposed to carrier gas and pressurizing gas, respectively, which gases are normally selected to be inert with respect to the source material. Accordingly, the MFCs may be operated at room temperature without the risk of condensation of the source material vapor. Furthermore, an MFC is less expensive than an APR, which makes the assembly and method according to the present invention less costly than those disclosed by US'423. It is also worth mentioning that the bubbler of US'423 is particularly configured to enable switching of relatively short pulses (0.1-1 seconds) without a need of sending source material unused to a bypass. However, in applications requiring a continuous flow of source material vapor or relatively long pulses of source material vapor of about 20-30 seconds, the use of an MFC for establishing a constant and controlled flow is very convenient, and obviates the need for advanced control logic. Should short pulses be required, e.g. pulses on the order of a few seconds or shorter, a constant source material vapor flow may be established using the MFC, which flow may then be alternatingly and repeatedly switched between a bypass and a reactor by means of one or more valves.

These and other features and advantages of the invention will be more fully understood from the following detailed description of certain embodiments of the invention, taken together with the accompanying drawings, which are meant to illustrate and not to limit the invention.

### BRIEF DESCRIPTION OF THE DRAWINGS

FIG. 1 schematically illustrates a semiconductor processing device incorporating an exemplary embodiment of a bubbler assembly according to the present invention; and

FIG. 2 is a graph illustrating the relationship between the carrier gas flow rate and the source material vapor flow rate for five different pressurizing gas flow rates.

### DETAILED DESCRIPTION

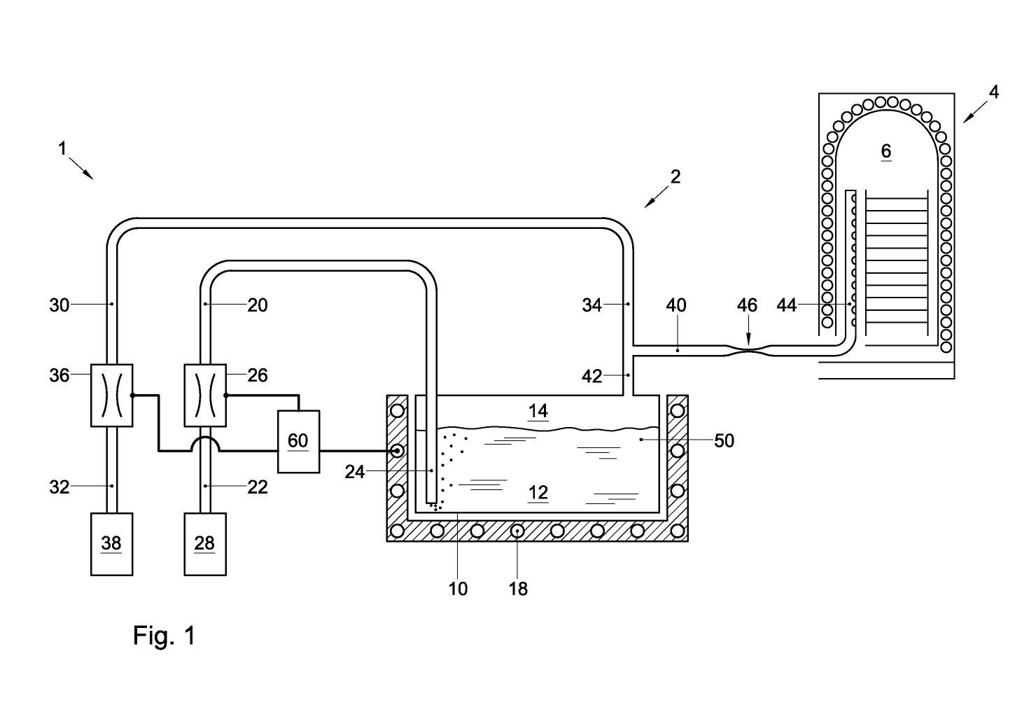

FIG. 1 schematically illustrates a semiconductor processing device 1 in the form of a vertical furnace. Since vertical furnaces per se are known in the art, a full piping and instrumentation diagram and other unnecessary structural detail have been omitted. For reasons of clarity FIG. 1 thus merely depicts an exemplary bubbler assembly 2 according to the present invention and a reactor 4 connected thereto. The construction of the bubbler assembly 2 according to the present invention is elucidated below with reference to FIG. 1.

The bubbler assembly 2 may comprise a generally sealed vessel 10, configured to contain a liquid source material 50 and its vapor. The vessel 10 may be made of any suitable material, including quartz or stainless steel, and may include a thermally insulating jacket that extends at least partially around it. The vessel 10 may further include a heater 18 that is configured to maintain the vessel 10 and/or its contents at a desired vessel temperature. The heater may extend within the interior vessel space of the vessel 10, or around the vessel space, for example within the vessel wall or adjacent to the vessel wall and/or over a top area of the vessel 10. The heater 18 may be an actual heat generating device (e.g. an electric heater comprising one or more resistive coils), a cooler, or a device capable of both heating and cooling (e.g. a heat pump), depending on the temperature of the environment in which the bubbler assembly 2 will be used and on the desired (range of) vessel temperature(s) that may have to be maintained. Since the vessel of the bubbler assembly 2 is configured to contain a liquid source material, the (range of) desired vessel temperature(s) may typically be in between the melting point and the boiling point of the selected source material. The heater 18 may preferably be a thermostatic heater, capable of automatically maintaining a certain vessel temperature that corresponds to a desired equilibrium vapor pressure of a source material to be contained in the vessel. To this end, and to enable adjustments of the vessel temperature, the heater 18 may be operatively connected to and be under the control of a control unit or controller 60.

The bubbler assembly 2 may further include a carrier gas supply line 20. An upstream end 22 of the carrier gas supply line 20 may be connected to a carrier gas supply 28, such as a gas cylinder or a gas mains. A downstream end 24 of the carrier gas supply line 20 may discharge in a lower portion 12 of the vessel 10. The term ‘lower portion of the vessel’ may generally refer to the region of the vessel space that, in use, holds the liquid phase of the source material. In an embodiment, the downstream end of the carrier gas supply line 24 may be fitted with a sparger, a frit or a similar device defining a plurality of small holes that promote the formation of small bubbles when gas is forced through them within a liquid phase. The carrier gas supply line 20 may include a mass flow controller 26, which may be operatively connected to and be under the control of the control unit 60.

The bubbler assembly 2 may also include a gas outlet line 40. An upstream end 42 of the gas outlet line 40 may be in fluid communication with an upper portion 14 of the vessel 10. The term ‘upper portion of the vessel’ may generally refer to the region of the vessel space that, in use, holds the vapor phase of the source material. A downstream end 44 of the gas outlet line 40 may be connected to the reactor 4, such that it is in, or may be brought in, fluid communication with the reactor space 6 thereof. In the depicted embodiment, the downstream end 44 of the gas outlet line 40 is shaped as a gas injector, having the form of a vertically extending tube with axially spaced apart gas injection holes, which is common in vertical furnaces.

The gas outlet line 40 may include a constriction or orifice 46. In one embodiment, the constriction 46 may have a variable or adjustable effective diameter and for example be embodied by a suitable type of controllable valve comprising an actuator that is operatively connected to the control unit 60. In another embodiment, the constriction 46 may have a fixed or non-adjustable diameter, and for example be embodied by a fixed diaphragm that is placed in the outlet line 40 and that provides for a small opening. In either case, the (effective) diameter of the constriction 46 may preferably be in, or be adjustable within, the range of 0.5-2.5 mm. In this text, the term ‘effective diameter’ may be construed to refer to the diameter of a circular opening that enables the same gas flow rate as the constriction 46.

In one embodiment, the gas outlet line 40 may be associated with a heater (now shown) that is configured to heat it, preferably to a temperature equal to or greater than the vessel temperature, in order to avoid cold spots in between the vessel 10 and the reactor 4 where condensation might occur.

The bubbler assembly 2 may further include a pressurizing gas supply line 30. An upstream end 32 of the pressurizing gas supply line 30 may be connected to a pressurizing gas supply 38, such as a gas cylinder or a gas mains. In one embodiment, a downstream end 34 of the pressurizing gas supply line 30 may be connected to and/or discharge in the upper portion 14 of the vessel 10. In another embodiment, such as the exemplary embodiment of FIG. 1, the downstream end 24 may be connected to and discharge in the gas outlet line 40, at a point upstream of the constriction 46. The pressurizing gas supply line 30 may include a mass flow controller, which may be operatively connected to and be under the control of the control unit 60.

In the embodiment of FIG. 1, the carrier gas supply 28 and the pressurizing gas supply 38 are depicted as distinct entities. Such a configuration may be advantageous in case the carrier gas to be used is different from the pressurizing gas. However, in embodiments of the bubbler assembly 2 wherein the carrier gas is to be the same as the pressurizing gas, the two gas supplies 28, 28 may actually coincide and be formed by a single gas supply.

The carrier gas and the pressurizing gas may preferably be inert or unreactive gases (at least with respect to the source material), such as nitrogen or noble gases.

The control unit 60 may be a programmable controller, and may for example include a central processing unit (CPU) capable of executing a desired control program. It may also comprise a memory for storing relationships between operational parameters (e.g. flow rate settings), input ports that enable the input of instructions and parameters relevant to the control program, and output ports that enable it to send control and/or power signals to devices attached thereto, such as the MFCs 26, 36, the heater 18, and the actuator of a controllable valve embodying the variable-diameter constriction 46.

Although not illustrated in FIG. 1, it should be apparent that the bubbler assembly 2 according to the present invention may include further components that are conventional parts of known bubblers. One skilled in the art will appreciate, for example, that the operation of the bubbler assembly 2 is dependent on the level of the liquid source material contained in the vessel 10. The bubbler assembly may therefore include a liquid level sensor, for example comprising a quartz tube with one slanted end and another opposite end coupled to a photo sensor, to enable monitoring of the liquid level. The photo sensor may be coupled to the control unit 60, which may be programmed to monitor the fluid level and to initiate automated refilling of the bubbler is the fluid level drops below a certain minimum. Also, additional isolation valves may be provided in carrier gas supply line 20, pressurizing gas supply line 30 and gas outlet line 40. Further, a vent line may be connected to each of the aforementioned gas lines to vent the gases directly to an exhaust and not flow the gases to reactor 4.

In the embodiment of the semiconductor processing device of FIG. 1, the reactor 4 is depicted as a vertical furnace batch reactor. The reactor 4 defines a reactor space or processing chamber 6 that is configured to receive and process a plurality of semiconductor substrates held by a wafer boat in a stacked fashion. As mentioned, the reactor 4 is coupled to the bubbler assembly 2 such that source material vapor may be introduced into the reactor space 6 via the gas outlet line 40, whose downstream ends is shaped as a gas injector that is located inside said reactor space. It is understood, however, that the use of a bubbler assembly 2 according to the present invention is not limited to vertical furnaces. In principle it may be used in combination with any device requiring controlled delivery of a vapor of a liquid source material, in particular other types of semiconductor processing devices, such as for example horizontal furnaces and single wafer reactors.

Now that the construction of the bubbler assembly 2 has been elucidated, attention is invited to its operation.

In use, the vessel 10 may be filled partly with a source material. The source material may typically be a reactant for a process to be carried out in the reaction space 6 of the reactor 4, such as a CVD or LPCVD process. Suitable source materials may include metal halides, including group IV (Si and Ge) metal halides, in particular metal fluorides and most in particular transition metal fluorides. By means of the heater 18, the vessel 10 and the source material contained therein may be heated/cooled to, and subsequently be maintained at, a suitable vessel temperature in between the melting point and the boiling point of the source material. For example, in case the source material is chosen to be tantalumpentafluoride (TaF₅), which has a melting point of just below 97° C. and a boiling point of about 230° C., the vessel 10 may be heated to a temperature in the range of about 105-115° C., e.g. 110° C., in order to ensure that the tantalumpentafluoride is in a liquid state and capable of vaporization.

When the vessel 10 contains the liquid source material, the mass flow controller 26 in the carrier gas supply line 20 may be controlled to provide for a steady flow of carrier gas from the carrier gas supply 28 into the vessel 10. As the downstream end 24 of the carrier gas supply line 20 discharges within the bulk of the liquid source material, small bubbles of carrier gas are formed. The liquid source material surrounding these bubbles vaporizes, saturating them with source material up to the equilibrium vapor pressure at the aforementioned vessel temperature. When the bubbles surface, the mixture of carrier gas and source material vapor accumulates in the upper portion or head region 14 the vessel. From there, it is subsequently outputted to the reactor space 6 via the gas outlet line 40. The constriction 46 in the gas outlet line 40 ensures that the control may be exercised over the outflow rate of the gas mixture, in particular when the process pressure maintained in the reactor space 6 is small compared to the pressure of the gas mixture in the vessel.

When no pressurizing gas is supplied via the pressurizing gas supply line 30, the flow rate at which the vaporized source material is delivered to the reactor space 6 may be controlled via the carrier gas flow rate, which in turn may be controlled via the mass flow controller 26. The relationship between the two gas flows is generally such that a greater carrier gas flow rate corresponds to a greater source material vapor flow rate, while a smaller carrier gas flow rate corresponds to a smaller source material vapor delivery flow rate. However, in case the equilibrium vapor pressure of the source material in vessel 10 is relatively large, in particular of the same order or greater than the pressure maintained in the reactor space 6, the delivery of small flows of source material vapor is problematic. This is because in such a situation the equilibrium vapor pressure of the source material itself is responsible for driving a substantial minimum flow of source material vapor through the gas outlet line 40 and into the reactor space 6, even when the carrier gas flow rate is reduced to zero.

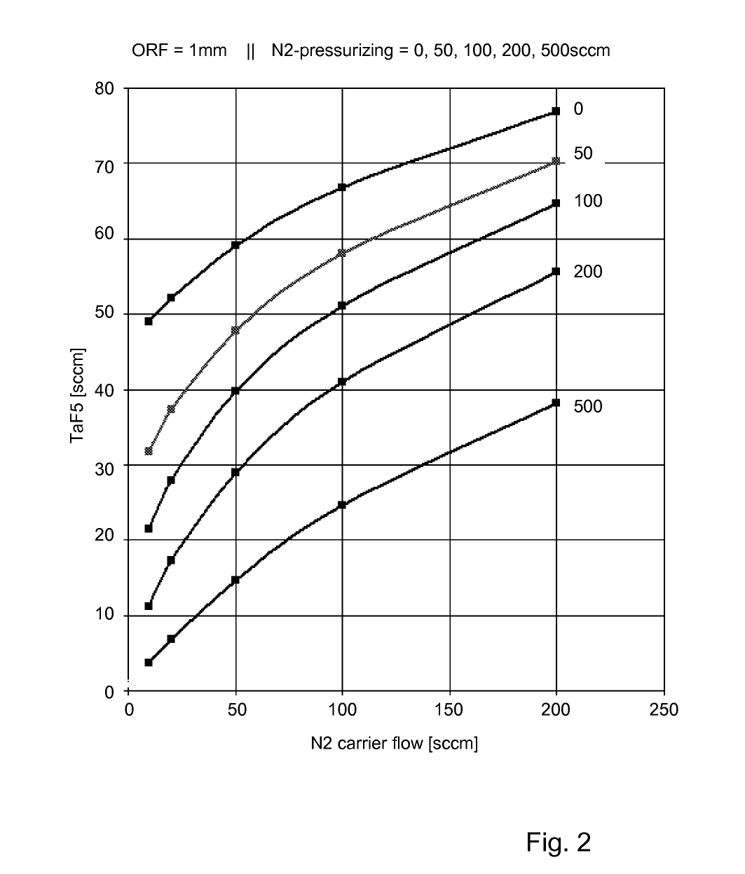

This latter case is diagrammatically illustrated in FIG. 2, which is based on a mathematical model of the bubbler assembly 2 of FIG. 1. FIG. 2 depicts the relationship between the carrier gas flow rate as controlled by the mass flow controller 26 (horizontal axis), and the flow rate of source material vapor into the reactor space 6 through the outlet line 40 (vertical axis). In the model, the carrier gas was taken to be nitrogen (N₂), while the source material was taken to be tantalumpentafluoride (TaF₅). The temperature of the source material was fixed at 110° C. The effective diameter of the constriction 26 was taken to be 1 mm, and tube length dependent flow resistances of the gas lines 20, 30, 40 were neglected. The diagram of FIG. 2 shows five curves, labeled “0”, “50”, “100”, “200” and “500”, respectively. The numbers reflect the flow rate of pressurizing gas, here nitrogen, in standard cubic centimeters per minute (sccm). Hence, the curve labeled “0” reflects the case wherein no pressurizing gas is supplied.

It is readily apparent from FIG. 2 that reducing the carrier gas flow rate to zero will not stop the flow of source material vapor to the reactor space 6. The equilibrium vapor pressure of the source material is apparently capable of maintaining a minimum flow of about 49 sccm. Accordingly, in the modeled setup it is not possible to control the flow rate of source material vapor in the range of about 0-49 sccm.

This problem may be overcome by providing for a suitable flow of pressurizing gas from the pressurizing gas supply 38 to the downstream end 34 of the pressurizing gas line 30. The solution is based on the fact that the concentration of source material in the gas mixture that is delivered to the reactor space 6 via outlet line 40 is determined by the ratio of the equilibrium vapor pressure of the source material and the overall gas pressure in the upper portion 14 of the vessel 10. Providing a flow of pressurizing gas to the upper portion 14 of the vessel 10, or to the outlet line 40 at a point upstream of the constriction 46, increases the overall gas pressure in the upper portion 14 of the vessel 30, and thus lowers the concentration of source material in the gas mixture.

The curves in FIG. 2 labeled “50”, “100”, “200” and “500” illustrate how this principle may be used to enable control over source material flow rates in the range of 4-49 sccm. The higher the pressurizing gas flow rate, the more of (the lower part of) that range is opened up and made controllable via the carrier gas flow rate. Accordingly, the bubbler assembly 2 enables control over small source material vapor flow rates, in particular when the equilibrium vapor pressure of the source material is high compared to the process pressure maintained in the reactor space 6 to which the source material vapor is to be fed. The curves in FIG. 2 additionally illustrate that the use of pressurizing gas increases the extent or width of the range of source material vapor flow rates that may be controlled (with a fixed range of carrier gas flow rates).

It will be clear that the operation of bubbler assembly 2 according to the present invention, and more in particular the source material vapor flow rate through the outlet line 40, depends on a number of parameters. These parameters include the carrier gas flow rate through the carrier gas supply line, the pressurizing gas flow rate through the pressurizing gas supply line, and the vessel temperature (which determines the equilibrium vapor pressure of the source material contained in the vessel). In addition, at least in embodiments wherein the diameter of the constriction 46 is adjustable, the diameter of the constriction 46 may also be regarded as a parameter. A change in any of these parameters may effect a change in the source material vapor flow rate through the outlet line 40. Furthermore, a change in the pressurizing gas flow rate through the pressurizing gas supply line 30, in the vessel temperature and/or in the diameter of the constriction 46 may alter the current relation between the carrier gas flow rate through the carrier gas supply line 20 and the source material vapor flow rate through the outlet line 40.

Although in one embodiment of the bubbler assembly 2 control over the parameters may be exercised manually, e.g. by manually adjusting the individual flow rate settings of the MFC's (for example by trial and error), control may preferably be exercised through a relatively fast and accurate automated process carried out by the control unit 60. In such an embodiment with automated parameter control, the control unit 60 may generally be configured to control the mass flow controller 26 in the carrier gas supply line 20 to control the carrier gas flow rate, the mass flow controller 36 in the pressurizing gas supply line 30 to control a pressurizing gas flow rate, the heater 18 to control the vessel temperature, and where applicable the actuator of a valve defining the diameter of the restriction 46, so as to obtain a desired target source material vapor flow rate through the outlet line 40. Controlling said parameters may typically include selecting and effecting a combination of values for these parameters corresponding to said target source material vapor flow rate. In a preferred embodiment, a combination of parameter values is selected such that a range of source material vapor flow rates of at least +/−10%, and more preferably at least +/−20%, around the target source material vapor flow rate is obtainable by (further) variation of the carrier gas flow rate alone. The combination of parameter values is thus chosen such that the selected carrier gas flow rate falls somewhere within the domain of available/selectable carrier gas flow rates, as opposed to at an extreme thereof, such that it can be decreased or increased further for making small adjustments to the source material vapor flow rate.

To enable the control unit 60 to efficiently select a combination of parameters that effects the desired target source material vapor flow rate, it may be fitted with one or more predetermined relationships between at least two of these parameters. Such a relationships may generally be stored in the control unit's memory in any suitable form, including tables with numerical values and mathematical formulas that describe the bubbler assembly's behavior in terms of its adjustable parameters.

Each of the individual curves in FIG. 2 is an example of a relationship between the flow rate of the carrier gas (through the carrier gas supply line 20) and the flow rate of source material vapor (through the outlet line 40). Based on such a relationship, the control unit 60 may efficiently select a carrier gas flow rate that corresponds to a target flow rate of source material vapor, and control the mass flow controller 26 in the carrier gas supply line accordingly. It is understood that each of the individual curves in FIG. 2 is valid only for a certain combination of the vessel temperature and the pressurizing gas flow rate. The bottom curve, for example is valid for a vessel temperature of 110° C. and a pressurizing gas flow rate of 500 sccm. The control unit 60 may therefore store a variety of relationships for different combinations of vessel temperatures and pressurizing gas flows, and in selecting a carrier gas flow rate that produces the target source material vapor flow rate apply the relationship that corresponds to the current vessel temperature and pressurizing gas flow rate settings.

It is noted that varying the source material vapor flow rate by varying the carrier gas flow rate at a constant pressurizing gas flow is just one example of how the source material vapor pressure flow can be varied. For instance, instead of varying the carrier gas flow rate alone, it is also possible to vary the carrier gas flow and the pressurizing gas flow simultaneously, e.g. such that the sum of both flows remains constant. In this way a larger dynamical range can be obtained as e.g. increasing the carrier gas flow and decreasing the pressurizing gas flow both result in an increase of source material vapor pressure.

Furthermore, the collection of the curves shown in FIG. 2, including the pressurizing gas flow rate associated with each individual curve, provides an example of a relationship between, on the one hand, the flow rate of the pressurizing gas, and on the other hand, relations between flow rates of the carrier gas and the source material vapor. Such a relationship may also be stored in the control unit's memory, so as to enable it to select a pressurizing gas flow rate that corresponds to a target relation between the flow rate of the carrier gas and the flow rate of the source material vapor, and to control the mass flow controller 36 in the pressurizing gas supply line 30 accordingly. Again, it is understood that the relationship defined by the collection of the curves and associated pressurizing gas flow rates depends on the vessel temperature. Accordingly, various of such relationships may be stored for various vessel temperatures. In selecting a certain pressurizing gas flow rate to produce the desired target relation between the carrier gas flow rate and the source material vapor flow rate, the control unit 60 may then apply the relation corresponding to the current vessel temperature setting.

As one skilled in the art will appreciate, the relationships depicted in FIG. 2 may all be described by one overall mathematical formula that interrelates all relevant adjustable parameters of the bubbler assembly 2. Providing the control unit 60 with this formula would obviate the need for storing multiple discrete relationships.

In an alternative embodiment, a control unit 60 may not make use of any predetermined relationship to select a combination of parameters that corresponds to a target source material vapor flow rate. It may, for example, adjust the parameters based on feed back, e.g. adjust the carrier gas flow rate based on a feed back circuit including a sensor that measures the source material vapor flow rate through the outlet line 40 and reports the measured flow rate to the control unit 60, so as to enable it to adjust the carrier gas flow rate until a target source material vapor flow rate is reached.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims. Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that particular features, structures, or characteristics of one or more embodiments may be combined in any suitable manner to form new, not explicitly described embodiments.

### LIST OF ELEMENTS

1 semiconductor processing device
2 bubbler assembly
4 reactor
6 reactor space
10 vessel
12 lower region of vessel (below liquid-gas interface)
14 upper portion or head region of vessel (above liquid-gas interface)
18 vessel heater
20 carrier gas supply line
22 upstream end of carrier gas supply line
24 downstream end of carrier gas supply line
26 carrier gas mass flow controller
28 carrier gas supply
30 pressurization gas supply line
32 upstream end of carrier gas supply line
34 downstream end of carrier gas supply line
36 pressurization gas mass flow controller
38 pressurization gas supply
40 outlet line
42 upstream end of the outlet line
44 downstream end of the outlet line
46 constriction
50 liquid source material
60 control unit

We claim:

1. A bubbler assembly, comprising:
a vessel configured to contain a liquid source material and its vapor;
a carrier gas supply line, a downstream end of which discharges in a lower portion of the vessel;
a gas outlet line, an upstream end of which is in fluid communication with an upper portion of the vessel;
a constriction, provided in the gas outlet line; and
a pressurizing gas supply line, a downstream end of which discharges in either the upper portion of the vessel or in the gas outlet line at a point upstream of the constriction.

2. The bubbler assembly according to claim 1, further comprising an inert gas source, wherein at least one of an upstream end of the carrier gas supply line and an upstream end of the pressurizing gas supply line is connected to said inert gas source.

3. The bubbler assembly according to claim 2, wherein the upstream end of the carrier gas supply line and the upstream end of the pressurizing gas supply line are both connected to the same inert gas source.

4. The bubbler assembly according to claim 1, further comprising:
a first mass flow controller (MFC) that is incorporated in the carrier gas supply line;
a second mass flow controller that is incorporated in the pressurizing gas supply line;
a heater that is associated with the vessel and configured to heat and/or cool the vessel and its contents; and
a control unit that is operably connected to the first MFC, the second MFC and the heater, said control unit being configured to control the first MFC to control a carrier gas flow rate through the carrier gas supply line, the second MFC to control a pressurizing gas flow rate through the pressurizing gas supply line, and the heater to control a vessel temperature, so as to obtain a target source material vapor flow rate through the outlet line.

5. The bubbler assembly according to claim 4, wherein the control unit is configured to control the first MFC to control the carrier gas flow rate through the carrier gas supply line based on a predetermined relationship between the carrier gas flow rate through the carrier gas supply line and the source material vapor flow rate through the outlet line, which relationship is stored in a memory of the control unit.

6. The bubbler assembly according to claim 4, wherein the control unit is configured to control the second MFC to control the pressurizing gas flow rate through the pressurizing gas supply line based on a predetermined relationship between, on the one hand, the pressurizing gas flow rate through the pressurizing gas supply line and, on the other hand, relations between the carrier gas flow rate through the carrier gas supply line and the source material vapor flow rate through the outlet line, so as to obtain a target relation between the carrier gas flow rate and the source material vapor flow rate.

7. The bubbler assembly according to claim 4, wherein the control unit is configured to obtain said target source material flow rate by simultaneously adjusting at least two of the carrier gas flow rate, the pressurizing gas flow rate and the vessel temperature.

8. The bubbler assembly according to claim 1, wherein a diameter of the constriction is in the range of 0.5-2.5 mm.

9. The bubbler assembly according to claim 1, wherein the vessel is at least partly enclosed by thermally insulating material.

10. The bubbler assembly according to claim 1, wherein the vessel is partly filled with a metal halide source material.

11. A semiconductor processing device, e.g. a vertical furnace, comprising:
a bubbler assembly according to claim 1; and
a reactor defining a reactor space in which the outlet line of the bubbler discharges.

12. A method for controlling a flow of vaporized liquid source material, comprising:
providing a bubbler assembly according to claim 1, wherein the vessel is partly filled with the liquid source material;
supplying a flow of carrier gas through the carrier gas supply line, which carrier gas supply line discharges below a surface level of the liquid source material in the vessel, such that the carrier gas bubbles through the liquid source material while being enriched in its vapor,
while at the same time supplying a flow of pressurizing gas through the pressurizing gas supply line, which pressurizing gas supply line discharges in one of the upper portion of the vessel above a surface level of the liquid source material, and the gas outlet line at a point upstream of the constriction; and
enabling a mixture comprising carrier gas, pressurizing gas and source material vapor to flow through the outlet line towards a downstream end thereof.

13. The method according to claim 12, wherein both the carrier gas and the pressurizing gas are inert with respect to the source material.

14. The method according to claim 12, wherein the carrier gas and the pressurizing gas are the same.

15. The method according to claim 12, further comprising:
controlling the carrier gas flow rate through the carrier gas supply line;
controlling the pressurizing gas flow rate through the pressurizing gas supply line; and
controlling the vessel temperature such that the source material in the vessel has a temperature in between the melting point and the boiling point of the source material,
so as to obtain a target source material vapor flow rate through the outlet line.

16. The method according to claim 15, further comprising:
providing a relationship between at least two of the carrier gas flow rate through the carrier gas supply line, the pressurizing gas flow rate through the pressurizing gas supply line, the vessel temperature and the flow rate of the source material vapor through the outlet line, and
wherein controlling the carrier gas flow rate, the pressurizing gas flow rate and the vessel temperature includes selecting and effecting a combination of values for these parameters based on said relationship in order to obtain said target source material vapor flow rate through the outlet line.

17. The method according to claim 16, wherein a combination of parameter values is selected such that a range of source material vapor flow rates of at least +/−10%, and more preferably at least +/−20%, around the target source material vapor flow rate is obtainable by variation of the carrier gas flow rate alone.

18. The method according to claim 15, further comprising:
controlling a diameter of the constriction, so as to obtain the target source material vapor flow rate through the outlet line.

19. The method according to claim 18, further comprising:
providing a relationship between the carrier gas flow rate through the carrier gas supply line, the pressurizing gas flow rate through the pressurizing gas supply line, the vessel temperature, the diameter of the constriction, and the flow rate of the source material vapor through the outlet line, and
wherein controlling the carrier gas flow rate, the pressurizing gas flow rate, the vessel temperature and the diameter of the constriction includes selecting and effecting a combination of values for these parameters based on said relationship in order to obtain said target source material vapor flow rate through the outlet line.

20. The method according to claim 12, wherein an equilibrium vapor pressure of the source material as contained in the vessel is greater than a pressure at a downstream end of the outlet line.
